(19) United States
(12) Patent Application Publication
(10) Pub. No.: US 2013/0229181 A1
(43) Pub. Date: Sep. 5, 2013

(54) Magnetic Resonance Facility Having a Cylindrical Patient Receiving Unit and Patient Capsule

(71) Applicants: Stephan Biber, Erlangen (DE); Björn Heismann, Erlangen (DE); Volker Matschl, Bamberg (DE); Sebastian Schmidt, Weisendorf (DE); Markus Vester, Nurnberg (DE)

(72) Inventors: Stephan Biber, Erlangen (DE); Björn Heismann, Erlangen (DE); Volker Matschl, Bamberg (DE); Sebastian Schmidt, Weisendorf (DE); Markus Vester, Nurnberg (DE)

(21) Appl. No.: 13/785,818

(22) Filed: Mar. 5, 2013

(30) Foreign Application Priority Data
Mar. 5, 2012 (DE) DE 102012203450.1

(51) Int. Cl. G01R 33/42

(52) U.S. Cl. CPC G01R 33/42
USPC 324/318

(57) ABSTRACT

A magnetic resonance facility having a cylindrical patient receiving unit includes a high-frequency shield. The high-frequency shield is disposed to enclose the patient receiving unit and shield at least one high-frequency coil from a gradient coil arrangement. The high-frequency shield is extendable to form a shielded chamber that shields the high-frequency coil from high-frequency signals outside the shielded chamber.

This application claims the priority benefit of German Patent Application No. DE 10 2012 203 450.1, filed Mar. 5, 2012, which is hereby incorporated by reference herein in its entirety.

### BACKGROUND

The present embodiments relate to a magnetic resonance facility having a cylindrical patient receiving unit that includes a high-frequency shield disposed to enclose the patient receiving unit and shield at least one high-frequency coil from a gradient coil arrangement.

Magnetic resonance facilities are known in the prior art. In these magnetic resonance facilities, a basic field magnet of a main magnetic unit may generate a powerful magnetic field. A high-frequency coil may be used to excite spin in a recording volume defined by gradient fields of a gradient coil arrangement such as, for example, a slice. When the magnetization thus generated decays, signals are generated. The generated signals may be measured using the same or another high-frequency coil (e.g., a receive coil). The high-frequency signals detected from the target volume (e.g., inside the body of a patient), are, however, extremely weak.

In order to distinguish this actual measurement signal from ambient interference and, at the same time, to be able to shield the outside world from the magnetic resonance transmit signals, magnetic resonance facilities may be accommodated in shielded cabins. Such cabins are extremely large and correspondingly expensive. Shielded cabins also make it difficult to integrate magnetic resonance facilities into existing structures. A further problem with shielding using a shielded cabin is that the many signals that serve to control the magnetic resonance facility may be fed into or out of the shielded cabin such that the signals do not cause interference or may be introduced from the outside.

Known shielded cabins may be provided with a door that is configured to be EMC-proof, through which the patient and/or the operator of the magnetic resonance facility may enter the shielded cabin. The problems relating to signals fed into the cabin are currently addressed by filters (e.g., a filter plate) configured such that electromagnetic interference may not penetrate into the interior of the shielded cabin or may only do so in a significantly attenuated manner.

A magnetic resonance facility directly adjoining a high-frequency shielded chamber was proposed in U.S. Pat. No. 4,613,820. The chamber described therein has at least one electrically conductive shielding wall that essentially encloses a predefined volume adjacent to the patient receiving unit. The shield surface is coupled to a unit that shields the main magnetic unit from a gradient coil arrangement or a high-frequency coil arrangement. The patient receiving unit is closed off by an end cap on the opposite side.

Therefore, a large shielded cabin, in which one or more people may stand upright, is flanged to the magnet.

U.S. Pat. No. 4,613,820 also requires a very large material outlay, as a very large shielded cabin flanged to the magnet is created. Present inside the overall space formed by the shielded cabin, the end cap, and the wall of the main magnetic unit are not only the high-frequency coils but also, for example, the gradient coil arrangement. This provides that complex high-frequency filtering of the gradient signals is to be provided.

### SUMMARY AND DESCRIPTION

The present embodiments may obviate one or more of the drawbacks or limitations in the related art. For example, an economical and effective way of shielding the measuring region of a magnetic resonance facility from external influences may be provided.

In one embodiment, a magnetic resonance facility includes a high-frequency shield that may be extended to form a shielded chamber that shields the high-frequency coil from high-frequency signals outside the shielded chamber.

Accordingly, the entire magnetic resonance facility may no longer be disposed in a shielded cabin, and a shielded cabin may no longer be coupled to the main magnetic unit. Instead, the high-frequency shield, which may be provided anyway and shields the high-frequency coils (e.g., the transmit and/or receive coils) from the gradient coils and, therefore, may have an axial length equal to the length of the gradient coil arrangement, is extended so that a shielded chamber with an adequate shielding effect is formed. Advantageously, the only parts inside the shielded chamber are thus the patient, the at least one high-frequency coil, and, optionally, a patient couch (e.g., a mechanically operated patient couch). In one embodiment, the gradient coils and, therefore, the entire gradient coil arrangement, are located outside the high-frequency shield and, therefore, outside the shielded chamber. The shielded chamber thus allows the complex high-frequency filtering of the gradient signals in the supply line to be dispensed with, as interference on these conductor systems is shielded by the shielded chamber.

A much smaller shielded cabin, in the form of the shielded chamber, is thus achieved. The shielded chamber thus avoids outside influences in the patient receiving unit (e.g., the measuring region). but is also able to shield signals generated by the high-frequency coils from the outside. The shielded high-frequency signals may lie in a defined frequency range such as for example, a frequency range that is open at the top and includes the magnetic resonance frequency of the magnetic resonance facility. For example, the frequency range may start at least 5% or at least 10% below the magnetic resonance frequency and includes all frequencies above the magnetic resonance frequency. The high-frequency shield, which shields the high-frequency coil from the gradient coil arrangement, may be configured to allow the passage of lower frequencies (e.g., to allow gradient formation within the patient receiving unit (the measuring region)).

One or more of the embodiments described herein may also be advantageous in that little is required in the way of materials, outlay, and, therefore, cost to achieve the high-frequency shield. The shielded chamber is attached directly to the magnetic resonance magnet and, thus, the magnetic resonance facility itself, and is arranged in such a compact manner that only the patient and the patient couch (optionally including a travel path) are present in the interior of the shielded chamber. Therefore, the axial length of the shielded chamber may be selected to accommodate a patient and/or be longer than the length of a patient couch. In one embodiment, the axial length of the shielded chamber may be at least two meters. To save materials, the shielded chamber may be made as small as possible to satisfy conditions with respect to the patient and the patient couch.

When the magnetic resonance facility is being set up, the shielded cabin is also installed, so that no additional installation outlay is used in this position (e.g., to prepare a space as a shielded cabin), thereby also reducing costs.

In one embodiment, one end or side of the cylindrical high-frequency shield may continue as or transition into a cylindrical component (e.g., a cylindrical component having a closed shield surface outside the high-frequency shield). This provides that the cylinder formed by the high-frequency shield is continued over the length of the gradient coil arrangement on at least one side, thereby creating further shielded space. For example, the shielded chamber component may project from the patient receiving unit on one side.

In another embodiment, the cylindrical component may be or include an open attenuating hollow conductor (e.g., an open attenuating hollow conductor having a length three times the diameter). The cylinder may have an open end on the component side so that an insertion opening is also present. The component cylinder therefore acts as a tunnel-type attenuating hollow conductor (e.g., for the TE21 hollow conductor mode excited by a birdcage antenna provided as a high-frequency antenna). If the cylindrical component is longer than the part of a patient's body that may project out of the patient receiving unit, the cylindrical component may also effectively suppress emission of the TEM coaxial mode derived from the patient, with which the patient would ultimately act as an internal conductor of a coaxial cable. This provides that the opening at the start of the tunnel formed by the component and the high-frequency shield does not have to be closed off.

A belt and/or chute for patient transport may provided inside the shielded chamber. Additionally, the shielded chamber may be configured to permit or allow a patient couch to have a sufficiently large travel path inside the shielded chamber. The patient may, however, be transported into the patient receiving unit in a different way (e.g., using a belt and/or a chute).

In the first embodiment described above, the elongated high-frequency shield therefore acts as a type of waveguide, which as a hollow conductor, may resolve problems in the axial direction by using a sufficiently long configuration, as described, and may provide adequate attenuation. In some embodiments, a continuous conductor surface may also be provided outside the high-frequency shield (e.g., not allowing the passage of low-frequency gradient excitation) to produce the cylindrical component, as will be examined in more detail below.

In one embodiment, in contrast to a cylindrical component open in the axial direction, the component may be closed in the axial direction by a conducting closing segment. The entire tunnel formed by the high-frequency shield and the cylindrical component may be much shorter, as the attenuating hollow conductor requirements relating to the forwarding of certain modes do not have to be observed; the shielded chamber is completely closed. However, with such an embodiment, there is to be another option for introducing the patient into the shielded chamber and, therefore, the patient receiving unit. For example, a closable flap or the like may be attached, as will be described in more detail below.

When more space is to be provided inside the shielded chamber, the cross section of the cylindrical component may be at least partially enlarged relative to the high-frequency shield in a region outside the patient receiving unit. For example, an enlarged segment of the shielded chamber may be created outside the patient receiving unit and, therefore, outside the main magnetic unit, in which other people (e.g., a person looking after the patient) may be temporarily accommodated. The change of cross section may also be associated with a change of shape. In other words, the shielded chamber may, for example, continue into the corresponding region of the component with a rectangular cross section or the like.

In one embodiment, the axial length of the component may be changed at least to some degree. For example, the axial length of the component may be compressed in the manner of a concertina (e.g., an accordion). When more space is required in front of the magnetic resonance facility, the axial length of the component may be temporarily shortened. This may be provided when an open tunnel is formed by the component that acts as an attenuating hollow conductor/waveguide, so that a shortening operation may be performed when no measurement is to take place, but the attenuating hollow conductor may be extended and, therefore, lengthened during measurement to produce the appropriate shielding properties. A concertina-type structure (e.g., a bellows) may be utilized. A number of segments of the same length are connected together via articulated connections, such that the segments may be folded together to rest against one another when the component is in the shortened state and form a continuous cylindrical surface when the component is extended (e.g., pulled out).

When the component or a component having a significant length only adjoins one side of the patient receiving unit, the other side may be closed by a conducting end surface that closes the patient receiving unit off from the outside and adjoins the high-frequency shield to form an adequate shield at this side. In other embodiments, another type of end cap, such as an end cap with a short component and a closing segment, may be used.

In one embodiment, two conducting end surfaces adjacent to the high-frequency shield may close off the patient receiving unit from the outside. Such an embodiment may be appropriate when the patient receiving unit of the magnetic resonance facility is of a pre-determined size that allows the patient receiving unit to accommodate an entire patient. The patient receiving unit may include a type of cover (e.g., a folding cover) at the front and rear. The cover may, like the high-frequency shield, have or be made of, for example, a multilayered, slotted shielding material that is connected in a conducting manner to the high-frequency shield. Before the actual magnetic resonance examination, the cover (e.g., the folding cover) or, in other words, the end surface, is closed on one side so that there is shielding inside the shielded chamber.

With conventional shielded cabins, there may be shielding attenuation of about 100 dB at the magnetic resonance frequency. The present embodiments may achieve at least the same attenuation even though the component of a shielded chamber is not located in the region of the high-frequency shield. In other words, the component, the closing segment, the end surface, or combinations thereof may attenuate the high-frequency signals by at least 90 dB (e.g., at least 100 dB) at the magnetic resonance frequency. In contrast, a high-frequency shield of a high-frequency transmit coil (e.g., a body coil) may have frequency selective shielding attenuation of around 30 dB in conventional magnetic resonance facilities. This is because the high-frequency shield is not configured as a continuous conducting surface (e.g., as a full copper shield), but is configured as a slotted shield that may include two layers so that the eddy currents induced by the gradient coil may be suppressed. If such a standard high-frequency shield is used as the basis for the shielded chamber in the magnetic resonance facilities described herein, there is quite low attenuation at the magnetic resonance frequency in this region.

Accordingly, in one or more of the present embodiments, the attenuation of the high-frequency signals of the magnetic resonance sequence in the region of the high-frequency shield is at least 60 dB, and, in some cases, at least 90 dB. This high level of attenuation may be achieved in any number of ways as described herein. In doing so, the housing of the main magnetic unit (e.g., outer vacuum container (OVC)), which also contributes a certain shielding effect and may be present in the radial direction, is considered.

In order to achieve such improved attenuation for the high-frequency shield, the high-frequency shield may have a number of conductive shielding layers such as, for example, a number of slotted, conductive shielding layers. In one embodiment, the high-frequency shield has three shielding layers. By increasing the number of shielding layers, the shielding effect may be increased in the region of the high-frequency shield, so long as certain distance is maintained between the individual layers. In one embodiment, attenuation for the magnetic resonance sequence may be increased to 60 dB, 90 dB, or higher (e.g., more than 100 dB).

In some embodiments, the end surfaces may be slotted and/or multilayered. Due to the proximity of the end surfaces to the gradient coils and the desire to avoid eddy currents, the end surfaces may include a number of layers that corresponds to the number of shielding layers.

The high-frequency coil may be or may include a body coil and/or at least one local coil disposed inside the high-frequency shield. In one embodiment, only local coils and no body coils may be used to reduce the overall attenuation requirement.

In one embodiment, the shielded chamber may include a closable access opening such as, for example, a flap for positioning a patient in the shielded chamber. The closable access opening may be located in the region of the cylindrical continuation component. The shielded chamber may thus be accessed even when there is no end opening. For example, access may be provided to an attenuating hollow conductor (e.g., using a closable access opening). The access opening may, as noted above, be a flap. In other words, the shielded chamber is folded up at the side so that the patient may be easily positioned on the patient couch or other supports inside the shielded chamber. The element closing the access opening has the same or is part of the shield surface of the shielded chamber. The element closing the access opening is, at least in the closed state, in conducting contact with the rest of the shield surface of the shielded chamber.

When a closed shielded chamber is utilized, the shielded chamber may include at least one opening suitable for the ingress of air into the shielded chamber and/or for communication into the shielded chamber. Openings may therefore be provided to allow the supply of air to and/or normal communication with a patient disposed inside the shielded chamber. The openings may, in one embodiment, be formed by at least one partial honeycomb-type configuration or structure of the shielded chamber, by a frequency-selective surface of the shielded chamber with a blocking frequency at the magnetic resonance frequency, by a hollow conductor structure, or combinations thereof. In order to achieve the shielding effect in the region of the openings as well, the openings may be configured with a blocking frequency at the magnetic resonance frequency (e.g., by a honeycomb structure or a frequency-selective surface). In other embodiments, hollow conductor structure may be employed. The cut-off frequency of the hollow conductor structure may be, for example, much higher than the magnetic resonance frequency

The shielded chamber is formed by an at least largely conductive shield surface that may be slotted and/or multilayered (e.g., in the region of the high-frequency shield and the like). Further structural components such as, for example, a support configured to at least partially support the shield surface and the like may be provided. Supports like the ones already known for use with high-frequency shields may be used.

In one embodiment, the shielded chamber may be formed by an axially movable patient capsule. The patient capsule may be removed from the patient receiving unit. The shielded chamber may thus be realized or formed by a structural unit (e.g., the patient capsule) that may be positioned in an axially movable manner inside the patient receiving unit and may be removed from the magnetic resonance facility. The capacity of such a patient capsule for axial movement may be achieved by, for example, corresponding guide facilities (e.g., a rail system), into which the patient capsule is introduced. In other embodiments, axial movement may be accomplished in other ways. Such a shielded chamber has advantages, for example, when a magnetic resonance facility includes a number of such patient capsules (e.g., a number of identical patient capsules). A patient may be prepared for the examination outside the magnetic resonance facility (e.g., by positioning local coils and giving instructions), while recordings are being actuated of another patient in a different patient capsule. This significantly increases the effective usage time of a magnetic resonance facility, as a large proportion of working time is invested in preparing and positioning the patient. For example, a plurality of patient capsules in which patients may be prepared outside the patient receiving unit before then being introduced into the patient receiving unit may be utilized.

In addition to the magnetic resonance facility, one or more of the present embodiments relate to a patient capsule for introduction into a cylindrical patient receiving unit of a magnetic resonance facility, (e.g., one or more of the magnetic resonance facilities described herein). The patient capsule includes a high-frequency shield having at least the axial length of a gradient coil arrangement of the magnetic resonance facility. The high-frequency shield is extendible to form a shielded chamber that shields at least one high-frequency coil from high-frequency signals outside the shielded chamber. Any or all of the embodiments described herein relating to the shielded chamber and its implementation, as set out with reference to one or more magnetic resonance facilities, apply in a similar manner to the patient capsule in which a patient may, advantageously, be prepared for the examination outside the patient receiving unit of the magnetic resonance facility. The patient capsule may include not only the high-frequency shield and the other components of the shielded chamber but also a patient couch that may be reached, for example, via an access opening, as described herein, to position the patient. A body coil may be provided coaxially and inside the high-frequency shield and may form a part of the patient capsule. In other embodiments, local coils may be provided. The local coils may be fastened to the patient as high-frequency coils for producing a magnetic resonance recording.

Once the patient has been prepared, the patient capsule may be introduced into the patient receiving unit of the magnetic resonance facility using, for example, a suitable guide system (e.g., a rail system or the like), with the high-frequency shield being positioned coaxially with and adjacent to the gradient coils of the gradient coil arrangement.

### BRIEF DESCRIPTION OF THE DRAWINGS

FIG. 1 shows one embodiment of a magnetic resonance facility;

FIG. 2 shows a cross section through the magnetic resonance facility of FIG. 1;

FIG. 3 shows an outline of an exemplary structure of a high-frequency shield;

FIG. 4 shows one embodiment of a modified cylindrical component;

FIG. 5 shows another embodiment of a magnetic resonance facility;

FIG. 6 shows yet another embodiment of a magnetic resonance facility;

FIG. 7 shows a cross section through the magnetic resonance facility of FIG. 6;

FIG. 8 shows one embodiment of a patient capsule;

FIG. 9 shows an exemplary cylindrical component adjustable in a lengthwise direction; and

FIG. 10 shows the cylindrical component of FIG. 9 in a compressed state.

### DETAILED DESCRIPTION OF THE DRAWINGS

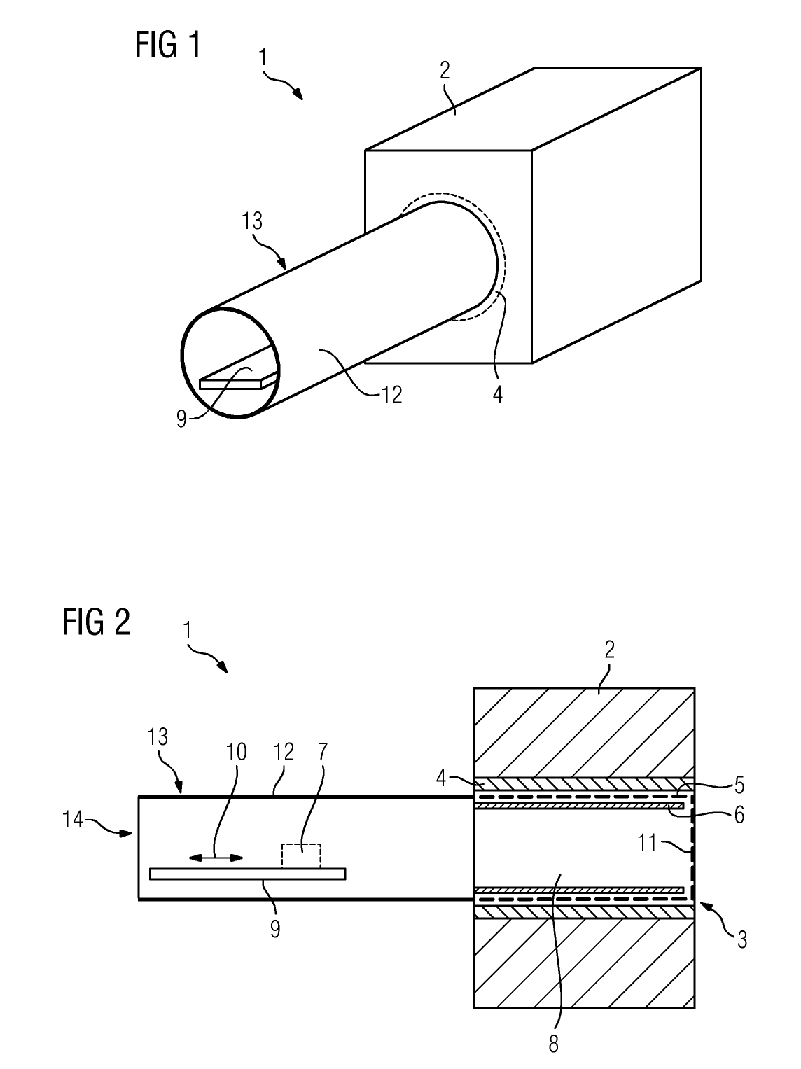

FIG. 1 and FIG. 2 illustrate one embodiment of a magnetic resonance (MR) facility 1 (e.g., an MR system or an MR device), with FIG. 1 showing a perspective view of the MR facility 1 and FIG. 2 showing a longitudinal section of the MR facility 1.

The magnetic resonance facility 1 includes a main magnetic unit 2. Though not depicted herein for the sake of clarity, superconducting windings are disposed in the main magnetic unit 2. The superconducting windings generate the basic field of the MR facility 1. The main magnetic unit 2 has a cylindrical hole 3. A gradient coil arrangement 4 may be provided in the cylindrical hole 3 adjacent to the main magnetic unit 2 or, in some embodiments, may be integrated in the main magnetic unit 2.

Further inside is a high-frequency shield 5, via which high-frequency coils such as, for example, a body coil 6 and an outlined local head coil 7 are shielded from the gradient coil arrangement 4 during imaging. The high-frequency coil arrangement 6 defines the size of the patient receiving unit 8, into which the patient may be introduced via a patient couch 9 (see arrow 10 in FIG. 1).

The high-frequency shield 5 may be extended to form a shielded chamber in the imaging region of the patient receiving unit 8, such that electromagnetic interference signals that may interfere with the imaging operation (e.g., with respect to the high-frequency coils 6, 7) may be kept out of the imaging region, and high-frequency signals from the high-frequency coils 6, 7 may not negatively impact the environment of the magnetic resonance facility 1. The shielded chamber thus formed therefore replaces a shielded cabin, in which the entire magnetic resonance facility 1 would otherwise be disposed.

The MR facility 1 has a rear end surface 11 that is a continuation of the high-frequency shield 5 and closes off one side or end of the patient receiving unit 8 in this direction. The other end of the high-frequency shield 5 is continued as or transitions into a cylindrical component 13 having a closed shield surface 12.

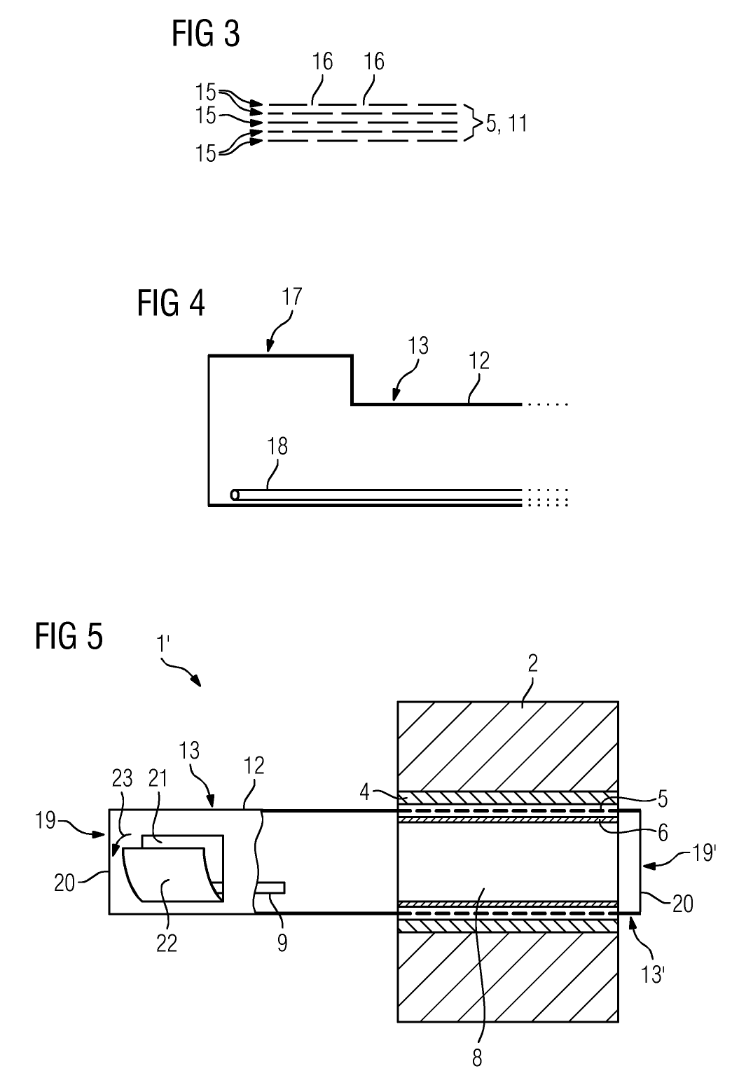

The closed shield surface 12 distinguishes the component 13 from the high-frequency shield 5. The high-frequency shield 5 is at least partially slotted and multilayered, as the low frequencies of the gradient fields generated by the gradient coils of the gradient coil arrangement 4 are to penetrate into the receiving region in the patient receiving unit. At the same time, eddy currents and the like triggered by the gradient coils are to be avoided on the high-frequency shield, as will be examined in more detail below with reference to FIG. 3. The end surface 11 is also slotted and multilayered like the high-frequency shield 5.

In contrast, the component 13 forms an open attenuating hollow conductor, such that the component 13 is left open at an end face. In other words, the component 13 includes an access opening 14. The patient couch 9, which in the illustrated exemplary embodiment is displaced mechanically, therefore has a longer travel path, as a patient may be positioned on the patient couch 9 and moved into the patient receiving unit through the access opening 14. In alternative embodiments, other patient transport systems (e.g., a belt and/or a chute) may be provided instead of or in addition to the patient couch 9.

In one embodiment, the length of the component 13 is three times the diameter of the cylindrical component 13, so that a tunnel-type attenuating hollow conductor ultimately results for the TE21 hollow conductor mode excited by the body coil 6 when the body coil 6 is, for example, configured as a birdcage antenna. As the component 13 is also longer than the part of a patient's body projecting out of the patient receiving unit 8, emission of the TEM coaxial mode derived from the patient may also be effectively suppressed.

The closed shield surface 12, which may be disposed on a support (not shown in detail here), results in a high attenuation of 100 dB in the region of the component 13. There may be a similarly high attenuation in the region of the high-frequency shield 5 and the end surface 11, when, as shown in FIG. 3, the high-frequency shield 5 has a larger number of shielding layers 15. For example, the high-frequency shield 5 has five shielding layers 15. Each of the shielding layers 15 is slotted (i.e., the layers have slits 16), so that the injection of eddy currents by the gradient coil arrangement 4 is largely avoided. A high attenuation of up to 100 dB may therefore also be achieved in the region of the high-frequency shield 5. The end surface 11 may be configured in a corresponding manner. In this embodiment, the distance between each of the individual shielding layers 15 is the same.

FIG. 4 depicts another embodiment of the MR facility 1 in which the embodiment depicted in FIG. 1 and FIG. 2 is modified. In this embodiment, the diameter of the component 13 is partially extended in or into a region 17 to allow better access. A belt 18 is also shown in FIG. 4 instead of a patient couch 9. The attenuating hollow conductor properties are to be correctly maintained.

Further exemplary embodiments are set out below, with identical components being assigned identical reference characters for the sake of simplicity.

FIG. 5 shows a longitudinal section through another embodiment of a magnetic resonance facility 1′. In FIG. 5, the component 13 is partially shown from the side.

In contrast to the end surface 11, in FIG. 5, the MR facility 1′ includes a shorter component 13′ present at the rear. The shorter component 13′ is closed off in the manner of an end cap by a closing segment 19′ with a conducting shield surface 20. In this embodiment, the cylindrical segment 13 is also closed off by such a closing segment 19 with a conducting shield surface 20, such that the segment 13 is completely closed. As a result, the segment 13 shown in FIG. 5 may be shorter than the component 13 shown in FIG. 1 and FIG. 2. In order to gain access to the now closed shielded chamber and the patient couch 19, an access opening 21 may be provided. The access opening 21 may be closed by an openable flap 22. The flap 22 may thus be opened, according to the arrow 23, to expose the access opening 21 and provide access to the shielded chamber and the patient couch 9. Such an access opening 21, with the flap 22, may be provided in the MR facility 1 depicted in FIG. 1 and FIG. 2 (e.g., to shorten the travel path of the patient couch 9).

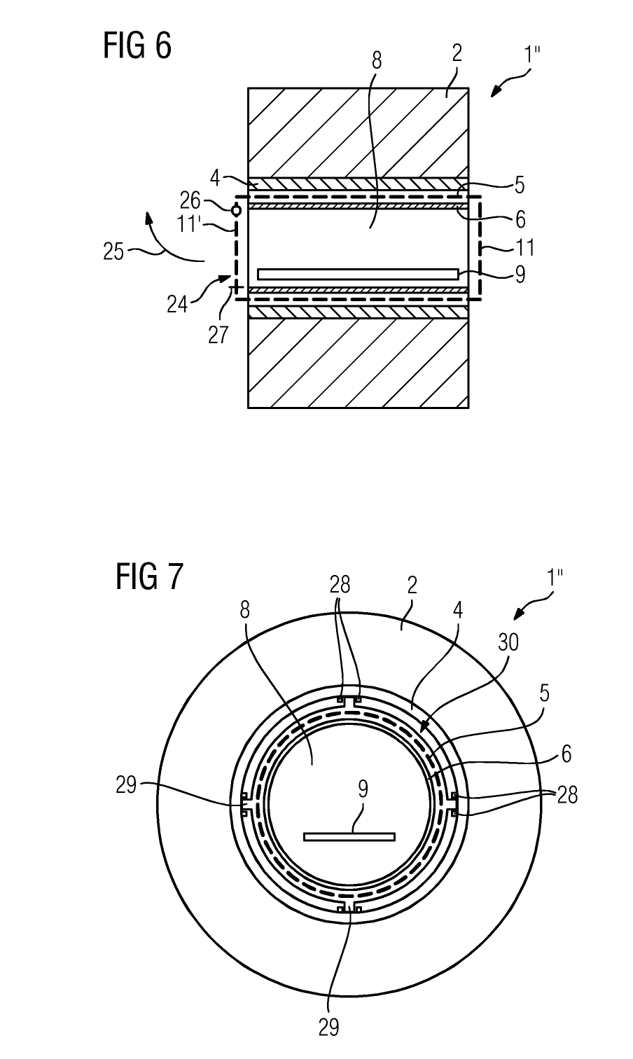

FIG. 6 shows yet another embodiment of a magnetic resonance facility 1″, in which the patient receiving unit 8 is closed off directly by end surfaces 11, 11′. Multiple layers of the end surface 11′ are disposed on a support such that an openable flap 24 (see arrow 25) results. The flap 24 is attached, for example, by a hinge 26 and may be closed securely by, for example, a closure 27.

An extremely compact arrangement is thus provided, with end surfaces 11 directly adjoining the high-frequency shield 5, so that when the flap 24 is closed during imaging, an effective shielded chamber results.

In the embodiment depicted by FIG. 6, the patient receiving unit 8 is suitable for accommodating the whole patient (e.g., the length of the patient couch 9). A patient capsule that includes the high-frequency shield 5, the end surfaces 11, 11′, the body coil 6, and the patient couch 9 in the interior may also be utilized or implemented. The patient couch 9 may, in some embodiments, be removable so that the patient may be positioned thereon before the patient couch 9 is introduced.

FIG. 7 shows a cross section through the magnetic resonance facility 1″. As shown in FIG. 7, guides 28 may be positioned inward from the gradient coil arrangement 4. The guides 28 match corresponding guide projections 29 of a patient capsule 30 configured as described. This allows the patient capsule 30 to be introduced into the patient receiving unit 8 of the magnetic resonance facility 1″.

In other embodiments, the shielded chamber is not to be implemented as a patient capsule 30, but is permanently integrated.

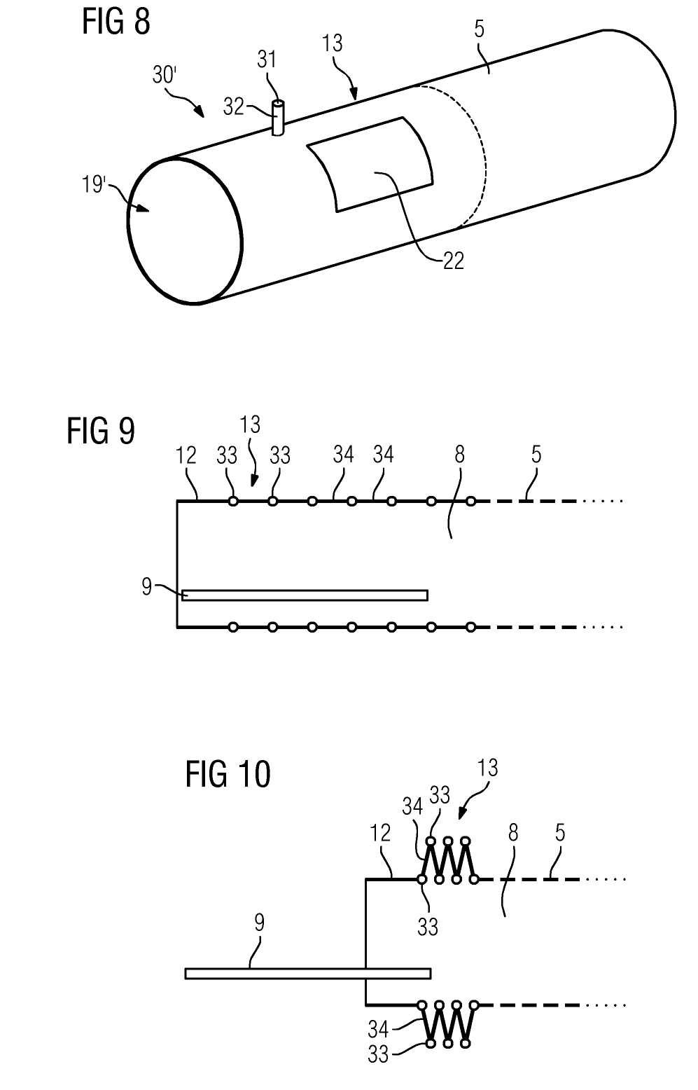

FIG. 8 shows a basic outline of a further embodiment of a patient capsule 30′ that includes both the high-frequency shield 5 and a component 13 that projects out of the magnetic resonance facility, as described above, and is closed off by a closing segment 19. The interior of the patient capsule 30′ is again accessible via, for example, an access opening closed off by, for example, a flap 22.

In some embodiments, only local coils are used (e.g., the local coils are also used as transmit coils). The attenuation requirements in the region of the high-frequency shield 5 and, where applicable, the end surfaces 11, 11′ are thus less stringent.

In embodiments in which the shielded chamber or patient capsule 30, 30′ is closed, openings suitable for the ingress of air into the shielded chamber and/or for communication into the shielded chamber, as shown, for example, in FIG. 8, may be provided. As shown in FIG. 8, the openings may be formed by a hollow conductor structure 32. Alternatively, a shield surface of the shielded chamber may include openings such that the shield surface is at least partially configured in the manner of a honeycomb structure. Further, a frequency-selective shield surface that has a blocking frequency at the magnetic resonance frequency may be provided for the shielded chamber.

FIGS. 9 and 10 illustrate further modifications that may be made to the embodiment depicted in FIGS. 1 and 2. As shown in FIGS. 9 and 10, the shield surface 12 of the component 13 partially divided into sub-segments 34 connected by articulations 33. As shown in FIG. 10, this allows the length of the component 13 to be shortened (e.g., compressed) in the manner of a concertina (e.g., an accordion) due to the articulations 33, so that the patient couch 9 is free and may be easily loaded. Such an embodiment may be particularly advantageous when the component 13 is embodied as an open attenuating hollow conductor.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

1. A magnetic resonance facility having a cylindrical patient receiving unit, the magnetic resonance facility comprising:
a high-frequency shield disposed to enclose the patient receiving unit and shield at least one high-frequency coil from a gradient coil arrangement,
wherein the high-frequency shield is configured to be extended to form a shielded chamber, the shielded chamber configured to shield the at least one high-frequency coil from high-frequency signals outside the shielded chamber.

2. The magnetic resonance facility as claimed in claim 1, wherein the shielded chamber has an axial length selected to accommodate a patient, selected to be longer than a length of a patient couch, or selected to accommodate the patient and to be longer than the length of the patient couch.

3. The magnetic resonance facility as claimed in claim 1, wherein the axial length of the shielded chamber is at least two meters.

4. The magnetic resonance facility as claimed in claim 1, wherein the high-frequency shield is cylindrical, and
wherein the cylindrical high-frequency shield is continued, at least to one side, in the manner of a cylindrical component.

5. The magnetic resonance facility as claimed in claim 4, wherein the cylindrical component has a closed shield surface outside the high-frequency shield.

6. The magnetic resonance facility as claimed in claim 4, wherein the cylindrical component is configured as an open attenuating hollow conductor.

7. The magnetic resonance facility as claimed in claim 6, wherein the open attenuating hollow conductor has a diameter and a length three times as long as the diameter.

8. The magnetic resonance facility as claimed in claim 5, further comprising a belt, a chute, or a belt and a chute provided for patient transport inside the shielded chamber.

9. The magnetic resonance facility as claimed in one of claim 4, wherein the cylindrical component is closed in the axial direction by a conducting closing segment.

10. The magnetic resonance facility as claimed in claim 4, wherein the cross section of the cylindrical component has a larger diameter than the high-frequency shield in a region outside the patient receiving unit.

11. The magnetic resonance facility as claimed in claim 4, wherein an axial length of the cylindrical component is adjustable.

12. The magnetic resonance facility as claimed in claim 11, wherein the axial length of the cylindrical component is compressible in the manner of an accordion.

13. The magnetic resonance facility as claimed in claim 1, further comprising two conducting end surfaces that close off the patient receiving unit from outside adjacent to the high-frequency shield.

14. The magnetic resonance facility as claimed in claim 1, wherein high-frequency signals of a magnetic resonance sequence in a region of the high-frequency shield have an attenuation of at least 60 dB.

15. The magnetic resonance facility as claimed in claim 1, wherein the attenuation is at least 90 dB.

16. The magnetic resonance facility as claimed in claim 1, wherein the high-frequency shield has a number of conductive shielding layers.

17. The magnetic resonance facility as claimed in claim 1, wherein the high-frequency shield has a number of slotted, conductive shielding layers.

18. The magnetic resonance facility as claimed in claim 1, wherein the high-frequency shield has more than three slotted conductive shielding layers.

19. The magnetic resonance facility as claimed in claim 1, further comprising a body coil, at least one local coil, or the body coil and the at least one local coil, disposed or disposable in the manner of a high-frequency coil inside the high-frequency shield.

20. The magnetic resonance facility as claimed in claim 1, wherein the shielded chamber has a closable access opening for positioning a patient in the shielded chamber.

21. The magnetic resonance facility as claimed in claim 20, wherein the closable access opening is a flap.

22. The magnetic resonance facility as claimed in claim 4, wherein the shielded chamber has a closable access opening for positioning a patient in the shielded chamber, the closable access opening being positioned in a region of the cylindrical component.

23. The magnetic resonance facility as claimed in claim 1, wherein the shielded chamber is formed by an axially movable patient capsule.

24. The magnetic resonance facility as claimed in claim 23, wherein the axially movable patient capsule is removable from the cylindrical patient receiving unit.

25. A patient capsule for introduction into a cylindrical patient receiving unit of a magnetic resonance facility, the patient capsule comprising:
a high-frequency shield having an axial length at least equal to an axial length of a gradient coil arrangement of the magnetic resonance facility,
wherein the high-frequency shield is extendable to form a shielded chamber, the shielded chamber configured to shield at least one high-frequency coil from high-frequency signals outside the shielded chamber.
